(19) United States
(12) Patent Application Publication
(10) Pub. No.: US 2017/0290161 A1
(43) Pub. Date: Oct. 5, 2017

(54) ELECTRONIC COMPONENT WITH INTERPOSER

(71) Applicant: TAIYO YUDEN CO., LTD., Tokyo (JP)

(72) Inventors: Tetsuo SHIMURA, Takasaki-shi (JP); Yousuke NAKADA, Takasaki-shi (JP)

(21) Appl. No.: 15/473,299

(22) Filed: Mar. 29, 2017

(30) Foreign Application Priority Data
Apr. 5, 2016 (JP) 2016-075629

(51) Int. Cl. H05K 1/18; H05K 1/11; H01G 4/232; H01G 4/30; H01G 4/12

(52) U.S. Cl. CPC H05K 1/181; H01G 4/30; H01G 4/12; H01G 4/232; H05K 1/11; H05K 2201/10015; H05K 2201/10378

(57) ABSTRACT

In an embodiment, a multilayer ceramic capacitor with interposer CWI1 has adhesive material parts 40 provided between the multilayer ceramic capacitor 10 and interposer 20, and the adhesive material parts 40 include space-setting members 41 for setting the spacing between the multilayer ceramic capacitor 10 and interposer 20. The electronic component with interposer can offer an improvement to the issue of its height dimension varying excessively.

### BACKGROUND

### Field of the Invention

The present invention relates to an electronic component with interposer, constituted by an electronic component and an interposer attached to it.

### Description of the Related Art

Patent Literatures 1 and 2 disclose multilayer ceramic capacitors with interposers relating to the foregoing. These multilayer ceramic capacitors with interposers are mounted on a circuit board, etc., for use, as shown in FIG. 4 of Patent Literature 1 and FIGS. 7 to 9 of Patent Literature 2.

It should be noted that, because a multilayer ceramic capacitor with interposer is a component combining a multilayer ceramic capacitor and an interposer, its production requires a step to attach an interposer to a multilayer ceramic capacitor, or specifically a step to connect the external electrodes of a multilayer ceramic capacitor to the connection electrodes provided on one face of an interposer.

With the multilayer ceramic capacitors with interposers disclosed in Patent Literatures 1 and 2, the aforementioned connection is implemented using solder or other joining material; if the joining material before curing is a paste, however, the height position of the multilayer ceramic capacitor relative to the interposer may change in the aforementioned connection step and the height dimension of the multilayer ceramic capacitor with interposer itself may vary excessively.

This means that, if the height dimension of the multilayer ceramic capacitor with interposer itself is greater than the sum of the reference height dimension and the positive tolerance, then mounting the multilayer ceramic capacitor with interposer on a circuit board, etc., as mentioned earlier by means of installing it on the circuit board, etc., using a mounter gives rise to a concern that due to an excessive force applied by the mounter the multilayer ceramic capacitor may crack, chip or otherwise suffer damage as a result. On the other hand, if the height dimension of the multilayer ceramic capacitor with interposer itself is less than the sum of the reference height dimension and the negative tolerance, then mounting the multilayer ceramic capacitor with interposer on a circuit board, etc., as mentioned earlier by means of installing it on the circuit board, etc., using a mounter gives rise to another concern that the multilayer ceramic capacitor with interposer may not be installed properly because it is not positioned close enough to the circuit board, etc. These concerns can also occur with other electronic components with interposers whose electronic component part is not a multilayer ceramic capacitor.

### BACKGROUND ART LITERATURES

[Patent Literature 1] Japanese Patent Laid-open No. 2014-187315

[Patent Literature 2] Japanese Patent Laid-open No. 2015-135910

### SUMMARY

An object of the present invention is to provide an electronic component with interposer that offers an improvement to the issue of its height dimension varying excessively.

Any discussion of problems and solutions involved in the related art has been included in this disclosure solely for the purposes of providing a context for the present invention, and should not be taken as an admission that any or all of the discussion were known at the time the invention was made.

To achieve the aforementioned object, the electronic component with interposer pertaining to the present invention represents an electronic component with interposer constituted by an electronic component and an interposer attached to it, wherein adhesive material parts are provided between the electronic component and the interposer and the adhesive material parts include space-setting members for setting the spacing between the electronic component and the interposer.

According to the electronic component with interposer pertaining to the present invention, an improvement can be made in that the height dimension of the electronic component with interposer itself does not vary excessively.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description which follows.

### BRIEF DESCRIPTION OF THE DRAWINGS

These and other features of this invention will now be described with reference to the drawings of preferred embodiments which are intended to illustrate and not to limit the invention. The drawings are greatly simplified for illustrative purposes and are not necessarily to scale.

FIG. 1 is a top view of a multilayer ceramic capacitor with interposer pertaining to the first embodiment of the present invention.

FIG. 2 is a side view in the width direction of the multilayer ceramic capacitor with interposer shown in FIG. 1.

FIG. 3 is a bottom view of the multilayer ceramic capacitor with interposer shown in FIG. 1.

FIG. 4 is an enlarged section view, along line S1-S1, of the multilayer ceramic capacitor shown in FIG. 1.

FIG. 5 is an enlarged section view, along line S2-S2, of the interposer shown in FIG. 3.

FIG. 6 is a drawing showing the placement positions of the adhesive material parts shown in FIG. 2.

FIGS. 7A and 7B are each a drawing showing a variation example in terms of the placement positions of the adhesive material parts shown in FIG. 6.

FIG. 8 is a top view of a multilayer ceramic capacitor with interposer pertaining to the second embodiment of the present invention.

FIG. 9 is a side view in the width direction of the multilayer ceramic capacitor with interposer shown in FIG. 8.

FIG. 10 is a drawing showing the placement positions of the adhesive material parts shown in FIG. 9.

### DESCRIPTION OF THE SYMBOLS

CWI1—Multilayer ceramic capacitor with interposer, 10—Multilayer ceramic capacitor, 11—Capacitor body, 11a—First internal conductor layer, 11b—Second internal conductor layer, 11c—Dielectric layer, 12—First external electrode, 13—Second external electrode, 20—Interposer, 21—Board, 22—First connection electrode, 23—Second connection electrode, 24—First mounting electrode, 25—Second mounting electrode, 26, 27—Connection conductor, 30—Terminal, 40—Adhesive material part, 41—Space-setting member, SP—Space, CWI2—Multilayer ceramic capacitor with interposer, 50—Multilayer ceramic capacitor, 51—Capacitor body, 52—First external electrode, 53—Second external electrode, 60—Interposer, 61—Board, 62—First connection electrode, 63—Second connection electrode, 64—First mounting electrode, 65—Second mounting electrode, 66, 67—Connection conductor, 70—Joining material, 80—Adhesive material part, 81—Space-setting member, SP—Space.

### DETAILED DESCRIPTION OF EMBODIMENTS

### First Embodiment

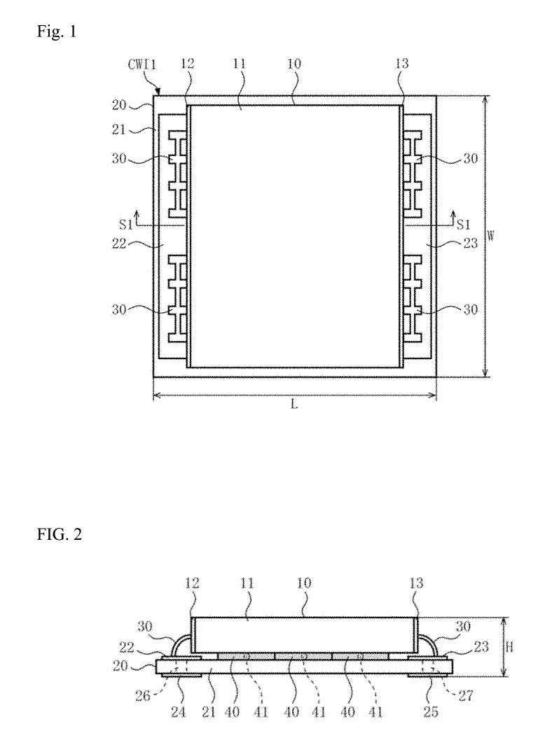

First, FIGS. 1 to 6 are used to explain the structure of the multilayer ceramic capacitor with interposer CWI1 pertaining to the first embodiment of the present invention.

The multilayer ceramic capacitor with interposer CWI1 shown in FIGS. 1 to 3 comprises a multilayer ceramic capacitor 10, an interposer 20, terminals 30, and adhesive material parts 40. The size of this multilayer ceramic capacitor with interposer CWI1 is specified by the length dimension L, width-direction dimension W, and height-direction dimension H shown in FIGS. 1 and 2.

The multilayer ceramic capacitor 10 has a capacitor body 11 of roughly rectangular solid shape, a first external electrode 12 of planar shape provided on one length-direction face of the capacitor body 10, and a second external electrode 13 of planar shape provided on the other length-direction face of the capacitor body 10.

As shown in FIG. 4, the capacitor body 11 houses a capacitance part (not accompanied by symbol) constituted by multiple first internal electrode layers 11a and multiple second internal electrode layers 11b stacked alternately in the height direction with dielectric layers 11c placed in between, where both width-direction sides and both height-direction sides of this capacitance part are covered with margin parts (not accompanied by symbol) made of dielectrics. Also, one length-direction end of each first internal electrode layer 11a is connected to the first external electrode 12, while the other length-direction end of each second internal electrode layer 1 lb is connected to the second external electrode 13.

For the material of the capacitor body 11, except for each first internal electrode layer 11a and each second internal electrode layer 11b, any dielectric ceramic whose primary component is barium titanate, strontium titanate, calcium titanate, magnesium titanate, calcium zirconate, calcium zirconate titanate, barium zirconate, titanium oxide, or the like, may be used. For the material of each first internal electrode layer 11a and that of each second internal electrode layer 11b, on the other hand, any good conductor whose primary component is nickel, copper, palladium, platinum, silver, gold, or alloy thereof, or the like, may be used.

While not illustrated, the first external electrode 12 and second external electrode 13 each have a two-layer structure comprising a base film contacting the exterior face of the capacitor body 11 and a surface film contacting the exterior face of this base film, or a multi-layer structure comprising a base film, a surface film and at least one intermediate film in between, or a single-layer structure comprising only a base film or surface film contacting the exterior face of the capacitor body 11. The base film is constituted by a baked film or plated film, for example, and preferably any good conductor whose primary component is nickel, copper, palladium, platinum, silver, gold, or alloy thereof, or the like, may be used for the material of this base film. The surface film is constituted by a plated film, for example, and preferably any good conductor whose primary component is copper, tin, palladium, gold, zinc, or alloy thereof, or the like, may be used for the material of this surface film. The intermediate film is constituted by a plated film, for example, and preferably any good conductor whose primary component is platinum, palladium, gold, copper, nicke,l or alloy thereof, or the like, may be used for the material of this intermediate film.

The interposer 20 has: a board 21 of roughly rectangular plate shape; a first connection electrode 22 and a second connection electrode 23, both having a roughly rectangular profile, provided on both length-direction sides of the top face of the board 21; a first mounting electrode 24 and a second mounting electrode 25, both having a roughly rectangular profile, provided on both length-direction sides of the bottom face of the board 21; two connection conductors 26 connecting the first connection electrode 22 and first mounting electrode 24; and two connection conductors 27 connecting the second connection electrode 23 and second mounting electrode 25.

As shown in FIGS. 1 and 2, the length-direction dimension and width-direction dimension of the board 21 are greater than the length-direction dimension and width-direction dimension of the multilayer ceramic capacitor 10, and accordingly the length-direction dimension of the board 21 corresponds to the aforementioned length dimension L, while the width-direction dimension of the board 21 corresponds to the aforementioned width dimension W. The first connection electrode 22, second connection electrode 23, first mounting electrode 24, and second mounting electrode 25 each have a roughly equivalent profile shape, and the first connection electrode 22 and first mounting electrode 24 are facing each other via the board 21, while the second connection electrode 23 and second mounting electrode 25 are facing each other via the board 21.

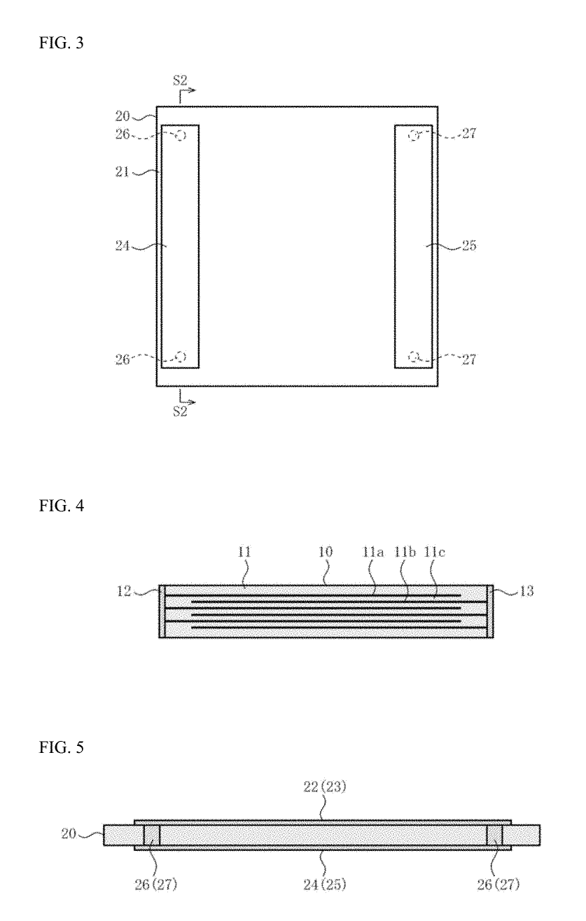

It should be noted that, while the width-direction dimensions of the first connection electrode 22, second connection electrode 23, first mounting electrode 24, and second mounting electrode 25 shown in FIGS. 1 and 3 are smaller than the width-direction dimension of the multilayer ceramic capacitor 10, respectively, these width-direction dimensions may each be identical to or slightly greater than the width-direction dimension of the multilayer ceramic capacitor 10.

The connection conductors 26 are present at positions corresponding to both width-direction ends of the first connection electrode 22 and first mounting electrode 24, respectively, while the connection conductors 27 are present at positions corresponding to both width-direction ends of the second connection electrode 23 and second mounting electrode 25, respectively. As shown in FIG. 5, the connection conductors 26 are each constituted by a conductor filling a through hole (not accompanied by symbol) formed in the board 21, to connect the first connection electrode 22 and first mounting electrode 24 that are facing each other in the thickness direction of the board 21. Also, the connection conductors 27 are each constituted by a conductor filling a through hole (not accompanied by symbol) formed in the board 21, to connect the second connection electrode 23 and second mounting electrode 25 that are facing each other in the thickness direction of the board 21.

It should be noted that, while the connection conductors 26, 27 shown in FIGS. 2, 3, and 5 each have a solid columnar shape, the desired connection can be achieved even when the connection conductors 26, 27 each have a hollow cylindrical shape.

For the material of the board 21, silicon dioxide, aluminum oxide, silicon nitride, zirconium oxide, or other ceramic, epoxy resin, phenol resin, polyimide resin, urea resin, melamine resin, unsaturated polyester resin, bis-maleimide resin, polyurethane resin, diallyl phthalate resin, silicone resin, cyanate resin, or other thermosetting synthetic resin, or combination of any such thermosetting synthetic resin and glass filler or other reinforcement filler, may be used. Also, for the materials of the first connection electrode 22, second connection electrode 23, first mounting electrode 24, and second mounting electrode 25, as well as for the materials of the connection conductors 26, 27, any good conductor whose primary component is nickel, copper, palladium, platinum, silver, gold, or alloy thereof, or the like, may be used.

The terminals 30 each have a shape integrally constituted by multiple linear parts running roughly parallel with each other as viewed from above (each is curved in its entirety as viewed from side) and a linear part running orthogonal thereto as viewed from above. Two terminals 30 are provided on the first external electrode 12 side, and another two are provided on the second external electrode 13 side, of the multilayer ceramic capacitor 10. The two terminals 30 on the first external electrode 12 side are connected on one end of each linear part to the first external electrode 12 using solder or other joining material (not illustrated), and they are also connected on the other end of each linear part to the first connection electrode 22 of the interposer 20 using solder or other joining material (not illustrated). Also, the two terminals 30 on the second external electrode 13 side are connected on one end of each linear part to the second external electrode 13 using solder or other joining material (not illustrated), and they are also connected on the other end of each linear part to the second connection electrode 23 of the interposer 20 using solder or other joining material (not illustrated).

For the material of each terminal 30, any metal such as nickel, copper, palladium, platinum, silver, gold, or alloy thereof, etc., may be used. Also, for the material of the joining material for connecting each terminal 30 to the external electrodes 12, 13 and connection electrodes 22, 23, any solder containing two or more metal elements selected from tin, copper, silver, nickel, germanium, gold, antimony, bismuth, zinc, gallium, and indium, or any resin adhesive, etc., in which silver grains, gold grains, etc., have been dispersed to add conductivity, may be used.

The adhesive material parts 40 are provided between the multilayer ceramic capacitor 10 and interposer 20, or specifically between the bottom face region of the multilayer ceramic capacitor 10 excluding the external electrodes 12, 13 on one hand, and the top face region of the interposer 20 facing this bottom face region, excluding the connection electrodes 22, 23, on the other.

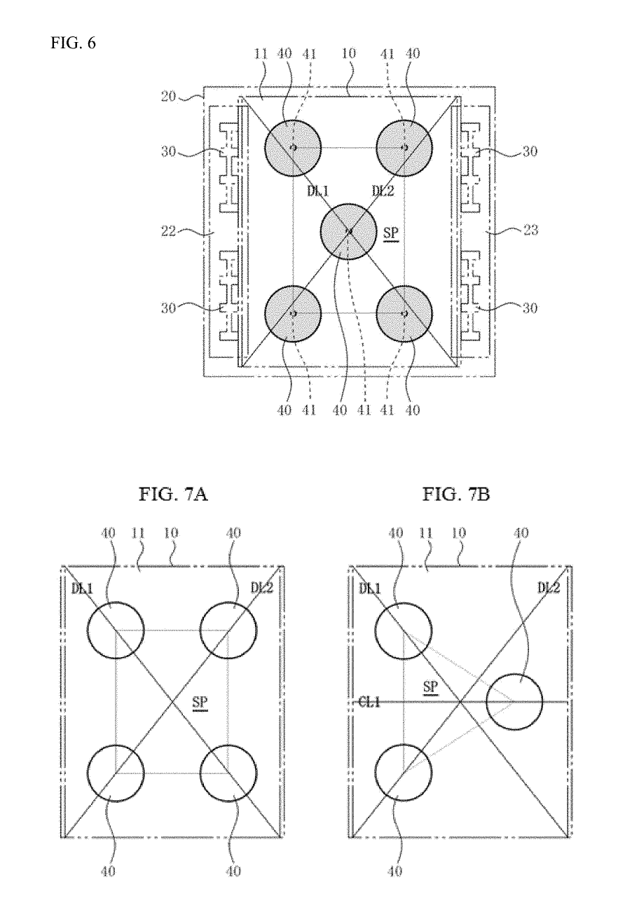

As shown in FIG. 6, five adhesive material parts 40 are used on the multilayer ceramic capacitor with interposer CWI1 shown in FIGS. 1 to 3. The adhesive material parts 40 each have a circular profile shape or other shape similar thereto, and are positioned away from each other. In other words, a continuous space SP exists around each adhesive material part 40 and this space SP opens to the outside. Also, while, in principle, the five adhesive material parts 40 each include at least one space-setting member 41 at their center position or other position close thereto, the one adhesive material part 40 at the center need not include any space-setting member 41.

In other words, the multilayer ceramic capacitor with interposer CWI1 shown in FIGS. 1 to 3 is such that its multilayer ceramic capacitor 10 and interposer 20 are bonded together by the five adhesive material parts 40. Also, the spacing between the multilayer ceramic capacitor 10 and interposer 20 is set by the space-setting members 41 included in at least four of the five adhesive material parts 40. This means that, because the spacing between the multilayer ceramic capacitor 10 and interposer 20 can be set by the space-setting members 41, the height-direction dimension H of the multilayer ceramic capacitor with interposer CWI1 itself shown in FIG. 2 does not vary excessively.

For the material of each adhesive material part 40, any adhesive whose primary component is epoxy resin, phenol resin, polyimide resin, urea resin, melamine resin, unsaturated polyester resin, bis-maleimide resin, polyurethane resin, diallyl phthalate resin, silicone resin, cyanate resin, or other thermosetting synthetic resin, or adhesive whose primary component is any such thermosetting synthetic resin containing glass filler or other reinforcement filler, may be used. Also, for the material of each space-setting member 41, silicon dioxide, aluminum oxide, silicon nitride, zirconium oxide, or other ceramic, iron, manganese, cobalt, nickel, copper, titanium, vanadium, molybdenum, tungsten, aluminum, magnesium, duralumin, stainless steel, carbon steel, or other metal, graphite, diamond, silicon, tungsten carbide, or other inorganic substance, polycarbonate resin, acrylic resin, phenol resin, or other synthetic resin, may be used. Furthermore, the shape of the space-setting member 41 may be a sphere, ellipsoid, cube, rectangular solid, or the like.

It should be noted that, although the number of adhesive material parts 40 and profile size of the adhesive material part 40 are limited by the extent of the aforementioned bottom face region of the multilayer ceramic capacitor 10, they are not limited to those in the embodiment shown in FIG. 6 so long as the aforementioned space SP can be ensured. If the bottom face region of the multilayer ceramic capacitor 10 is large, for example, the number of adhesive material parts 40 may be increased or the profile size of the adhesive material part 40 may be enlarged. If the bottom face region of the multilayer ceramic capacitor 10 is small, on the other hand, the number of adhesive material parts 40 may be decreased or the profile size of the adhesive material part 40 may be reduced.

Also, the profile shape of the adhesive material part need not be a circle or other shape similar thereto, and it may be oval, square, rectangular, or other shape, instead. Furthermore, the number of space-setting members 41 included in the adhesive material parts 40 need not be one, and it may be two or more instead.

Here, supplemental explanation on the placement positions of adhesive material parts 40 is given by citing an example where their profile shape is a circle or other shape similar thereto.

If there are five adhesive material parts 40 (refer to FIG. 6), preferably one adhesive material part 40 is placed so that it overlaps the point of intersection between the two diagonal lines DL1, DL2 drawn across the bottom face region of the multilayer ceramic capacitor 10, two adhesive material parts 40 are placed so that they overlap the diagonal line DL1, and two adhesive material parts 40 are placed so that they overlap the diagonal line DL2. In addition, more preferably four adhesive material parts 40 other than the one adhesive material part 40 at the center are placed so that their respective centers are positioned at the corners of a rectangle.

If there are four adhesive material parts 40 (refer to FIG. 7A), preferably two adhesive material parts 40 are placed so that they overlap, of the two diagonal lines DL1, DL2 drawn across the bottom face region of the multilayer ceramic capacitor 10, the diagonal line DL1, while two adhesive material parts 40 are placed so that they overlap the diagonal line DL2. In addition, more preferably the four adhesive material parts 40 are placed so that their respective centers are positioned at the corners of a rectangle.

If there are three adhesive material parts 40 (refer to FIG. 7B), preferably one adhesive material part 40 is placed so that it overlaps, of the two diagonal lines DL1, DL2 drawn across the bottom face region of the multilayer ceramic capacitor 10 and one width-direction center line CL1, the diagonal line DL1, while one adhesive material part 40 is placed so that it overlaps the diagonal line DL2, and one adhesive material part 40 is placed so that it overlaps the width-direction center line CL1. In addition, more preferably the three adhesive material parts 40 are placed so that their respective centers are positioned at the corners of an isosceles or regular triangle.

By adopting the aforementioned placement positions according to the number of adhesive material parts 40, the multilayer ceramic capacitor 10 can be supported in a stable manner with the adhesive material parts 40 and space-setting members 41, and high parallelism can be ensured for the multilayer ceramic capacitor 10 and interposer 20.

Next, preferred examples of how the multilayer ceramic capacitor with interposer CWI1 shown in FIGS. 1 to 3 is produced are explained using FIGS. 1 to 3 and 6.

### First Example of Production Method

For production, a multilayer ceramic capacitor 10, an interposer 20 and terminals 30, as shown in FIGS. 1 to 3, are prepared. Next, a paste for adhesive material part 40 is printed on the top face region of the interposer 20 excluding the connection electrodes 22, 23, by means of screen printing, gravure printing, or other printing method, to form the necessary number of uncured adhesive material parts 40 (refer to FIG. 6). Next, space-setting members 41 are embedded in the uncured adhesive material parts 40. This embedding step may be omitted by mixing the space-setting members 41 into the paste for adhesive material part 40 beforehand. Next, the multilayer ceramic capacitor 10 is installed on the interposer 20 by pressing its bottom face region, excluding the external electrodes 12, 13, onto the uncured adhesive material parts 40. Next, the uncured adhesive material parts 40 are cured by blowing hot air onto them, heating them in an oven, or using another method, to bond the multilayer ceramic capacitor 10 to the interposer 20. Next, two terminals 30 are installed on the first connection electrode 22 and second connection electrode 23 of the interposer 20, after which one end of each of the linear parts of the two terminals 30 on the first connection electrode 22 side is joined to the first external electrode 12 using solder or other joining material, while the other end of each of the linear parts is joined to the first connection electrode 22 using solder or other joining material, and at the same time one end of each of the linear parts of the two terminals 30 on the second connection electrode 23 side is joined to the second external electrode 13 using solder or other joining material, while the other end of each of the linear parts is joined to the second connection electrode 23 using solder or other joining material.

### Second Example of Production Method

For production, a multilayer ceramic capacitor 10, an interposer 20 and terminals 30, as shown in FIGS. 1 to 3, are prepared. Next, one end of each of the linear parts of two terminals 30 is joined to the first external electrode 12 side of the multilayer ceramic capacitor 10 using solder or other joining material, while one end of each of the linear parts of two terminals 30 is joined to the second external electrode 13 using solder or other joining material. Next, a paste for adhesive material part 40 is printed on the top face region of the interposer 20 excluding the connection electrodes 22, 23, by means of screen printing, gravure printing, or other printing method, to form the necessary number of uncured adhesive material parts 40 (refer to FIG. 6). Next, space-setting members 41 are embedded in the uncured adhesive material parts 40. This embedding step may be omitted by mixing the space-setting members 41 into the paste for adhesive material part 40 beforehand. Next, the multilayer ceramic capacitor 10 is installed on the interposer 20 by pressing its bottom face region, excluding the external electrodes 12, 13, onto the uncured adhesive material parts 40. Next, the uncured adhesive material parts 40 are cured by blowing hot air onto them, heating them in an oven, or using another method, to bond the multilayer ceramic capacitor 10 to the interposer 20. Next, the other end of each of the linear parts of the two terminals 30 on the first external electrode 12 side of the multilayer ceramic capacitor 10 is joined to the first connection electrode 22 of the interposer 20 using solder or other joining material, while at the same time the other end of each of the linear parts of the two terminals 30 on the second external electrode 13 side is joined to the second connection electrode 23 of the interposer 20 using solder or other joining material.

Next, the effects achieved by the multilayer ceramic capacitor with interposer CWI1 shown in FIGS. 1 to 3 are explained.

(1) The multilayer ceramic capacitor with interposer CWI1 has adhesive material parts 40 provided between the multilayer ceramic capacitor 10 and interposer 20, and the adhesive material parts 40 include space-setting members 41 for setting the spacing between the multilayer ceramic capacitor 10 and interposer 20. This means that, because the spacing between the multilayer ceramic capacitor 10 and interposer 20 can be set by the space-setting members 41, the height-direction dimension H of the multilayer ceramic capacitor with interposer CWI1 itself does not vary excessively. This removes concerns that the multilayer ceramic capacitor 10 may crack, chip, or otherwise suffer damage, or may not be installed properly when the multilayer ceramic capacitor with interposer CWI1 is installed on a circuit board, etc., using a mounter.

(2) The multilayer ceramic capacitor with interposer CWI1 has, around the adhesive material parts 40 between the multilayer ceramic capacitor 10 and interposer 20, a space SP that opens to the outside. This means that, even when the temperature of the interposer 20 rises in a state where the multilayer ceramic capacitor with interposer CWI1 is mounted on a circuit board, etc., this heat can be released to the outside by utilizing the space SP, which in turn keeps the temperature of the multilayer ceramic capacitor 10 from rising due to heat conduction from the interposer 20 and thereby prevents, to the maximum extent possible, any capacity drop or other functional problem that might otherwise occur in the multilayer ceramic capacitor 10 due to temperature rise.

(3) By providing three or more adhesive material parts 40 on the multilayer ceramic capacitor with interposer CWI1, the multilayer ceramic capacitor 10 can be supported in a stable manner by the adhesive material parts 40 and space-setting members 41.

### Second Embodiment

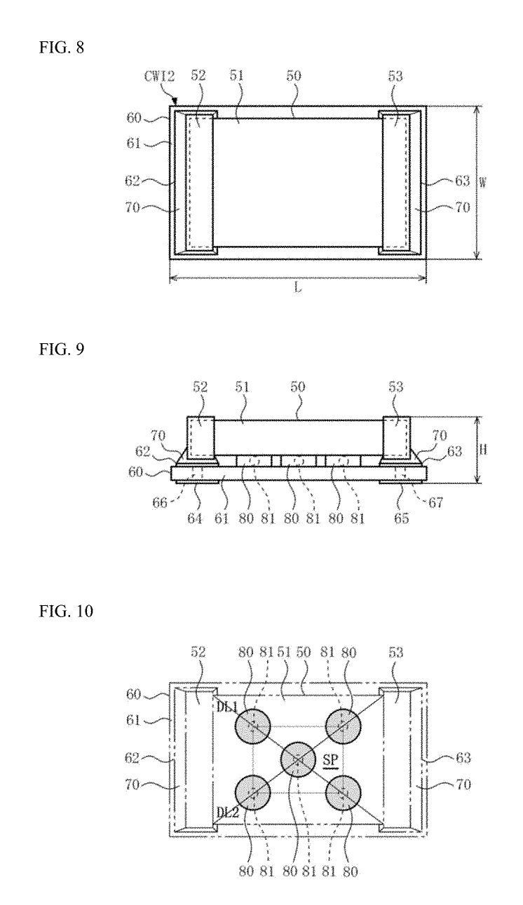

First, FIGS. 8 to 10 are used to explain the structure of the multilayer ceramic capacitor with interposer CWI2 pertaining to the second embodiment of the present invention.

The multilayer ceramic capacitor with interposer CWI2 shown in FIGS. 8 and 9 comprises a multilayer ceramic capacitor 50, an interposer 60, joining material 70, and adhesive material parts 80. The size of this multilayer ceramic capacitor with interposer CWI2 is specified by the length dimension L, width-direction dimension W, and height-direction dimension H shown in FIGS. 8 and 9.

The multilayer ceramic capacitor 50 has a capacitor body 51 of roughly rectangular solid shape, a first external electrode 52 of closed-bottom squared cylinder shape provided continuously on one length-direction face, parts of both width-direction faces, and parts of both height-direction faces, of the capacitor body 51, and a second external electrode 53 of closed-bottom squared cylinder shape provided continuously on the other length-direction face, parts of both width-direction faces, and parts of both height-direction faces, of the capacitor body 51.

The capacitor body 51 houses a capacitance part (not illustrated) constituted by multiple first internal electrode layers (not illustrated) and multiple second internal electrode layers (not illustrated) stacked alternately in the height direction with dielectric layers (not illustrated) placed in between, where both width-direction sides and both height-direction sides of this capacitance part are covered with margin parts (not illustrated) made of dielectrics. Also, one length-direction end of each first internal electrode layer is connected to the first external electrode 52, while the other length-direction end of each second internal electrode layer is connected to the second external electrode 53.

The material of the capacitor body 51, except for each first internal electrode layer and each second internal electrode layer, materials of each first internal electrode layer and each second internal electrode layer, and constitutions and materials of the first external electrode 52 and second external electrode 53, are the same as those described in <<First Embodiment>> above and therefore not explained.

The interposer 60 has: a board 61 of roughly rectangular plate shape; a first connection electrode 62 and a second connection electrode 63, both having a roughly rectangular profile, provided on both length-direction sides of the top face of the board 61; a first mounting electrode 64 and a second mounting electrode 65, both having a roughly rectangular profile, provided on both length-direction sides of the bottom face of the board 61; two connection conductors 66 connecting the first connection electrode 62 and first mounting electrode 64; and two connection conductors 67 connecting the second connection electrode 63 and second mounting electrode 65.

As shown in FIGS. 8 and 9, the length-direction dimension and width-direction dimension of the board 61 are greater than the length-direction dimension and width-direction dimension of the multilayer ceramic capacitor 50, and accordingly the length-direction dimension of the board 61 corresponds to the aforementioned length dimension L, while the width-direction dimension of the board 61 corresponds to the aforementioned width dimension W. The first connection electrode 62, second connection electrode 63, first mounting electrode 64, and second mounting electrode 65 each have a roughly equivalent profile shape, and the first connection electrode 62 and first mounting electrode 64 are facing each other via the board 61, while the second connection electrode 63 and second mounting electrode 65 are facing each other via the board 61.

It should be noted that, while the width-direction dimensions of the first connection electrode 62, second connection electrode 63, first mounting electrode 64, and second mounting electrode 65 shown in FIGS. 8 and 9 are greater than the width-direction dimension of the multilayer ceramic capacitor 50, respectively, these width-direction dimensions may each be identical to or slightly smaller than the width-direction dimension of the multilayer ceramic capacitor 50.

The connection conductors 66 are present at positions corresponding to both width-direction ends of the first connection electrode 62 and first mounting electrode 64, respectively, while the connection conductors 67 are present at positions corresponding to both width-direction ends of the second connection electrode 63 and second mounting electrode 65, respectively. The connection conductors 66 are each constituted by a conductor filling a through hole (not accompanied by symbol) formed in the board 61, to connect the first connection electrode 62 and first mounting electrode 64 that are facing each other in the thickness direction of the board 61. Also, the connection conductors 67 are each constituted by a conductor filling a through hole (not accompanied by symbol) formed in the board 61, to connect the second connection electrode 63 and second mounting electrode 65 that are facing each other in the thickness direction of the board 61.

It should be noted that, while the connection conductors 66, 67 shown in FIG. 9 each have a solid columnar shape, the desired connection can be achieved even when the connection conductors 66, 67 each have a hollow cylindrical shape.

The material of the board 61, materials of the connection electrodes 62, 63, materials of the mounting electrodes 64, 65, and materials of the connection conductors 66, 67, are the same as those described in <<First Embodiment>> above and therefore not explained.

As shown in FIGS. 8 and 9, the first external electrode 52 of the multilayer ceramic capacitor 50 is connected to the first connection electrode 62 of the interposer 60 by the joining material 70, while the second external electrode 53 of the multilayer ceramic capacitor 50 is connected to the second connection electrode 63 of the interposer 60 by the joining material 70. The material of the joining material 70 is the same as those described in <<First Embodiment>> above and therefore not explained.

The adhesive material parts 80 are provided between the multilayer ceramic capacitor 50 and interposer 60, or specifically between the bottom face region of the multilayer ceramic capacitor 50 excluding the external electrodes 52, 53 on one hand, and the top face region of the interposer 60 facing this bottom face region, excluding the connection electrodes 62, 63, on the other.

As shown in FIG. 10, five adhesive material parts 80 are used on the multilayer ceramic capacitor with interposer CWI2 shown in FIGS. 8 and 9. The adhesive material parts 80 each have a circular profile shape or other shape similar thereto, and are positioned away from each other. In other words, a continuous space SP exists around each adhesive material part 80 and this space SP opens to the outside. Also, in principle, while the five adhesive material parts 80 each include at least one space-setting member 81 at their center position or other position close thereto, the one adhesive material part 80 at the center need not include any space-setting member 81.

In other words, the multilayer ceramic capacitor with interposer CWI2 shown in FIGS. 8 and 9 is such that its multilayer ceramic capacitor 50 and interposer 60 are bonded together by the five adhesive material parts 80. Also, the spacing between the multilayer ceramic capacitor 50 and interposer 60 is set by the space-setting members 81 included in at least four of the five adhesive material parts 80. This means that, because the spacing between the multilayer ceramic capacitor 50 and interposer 60 can be set by the space-setting members 81, the height-direction dimension H of the multilayer ceramic capacitor with interposer CWI2 itself shown in FIG. 9 does not vary excessively.

The material of each adhesive material part 80, and material of each space-setting member 81, are the same as those described in <<First Embodiment>> above and therefore not explained.

It should be noted that, although the number of adhesive material parts 80 and profile size of the adhesive material part 80 are limited by the extent of the aforementioned bottom face region of the multilayer ceramic capacitor 50, they are not limited to those in the embodiment shown in FIG. 10 so long as the aforementioned space SP can be ensured. If the bottom face region of the multilayer ceramic capacitor 50 is large, for example, the number of adhesive material parts 80 may be increased or the profile size of the adhesive material part 80 may be enlarged. If the bottom face region of the multilayer ceramic capacitor 50 is small, on the other hand, the number of adhesive material parts 80 may be decreased or the profile size of the adhesive material part 80 may be reduced.

Also, the profile shape of the adhesive material part need not be circle or other shape similar thereto, and it may be oval, square, rectangular, or other shape, instead. Furthermore, the number of space-setting members 81 included in the adhesive material parts 80 need not be one, and it may be two or more instead.

Here, supplemental explanation on the placement positions of adhesive material parts 80 is given by citing an example where their profile shape is a circle or other shape similar thereto.

If there are five adhesive material parts 80 (refer to FIG. 10), preferably one adhesive material part 80 is placed so that it overlaps the point of intersection between the two diagonal lines DL1, DL2 drawn across the bottom face region of the multilayer ceramic capacitor 50, two adhesive material parts 80 are placed so that they overlap the diagonal line DL1, and two adhesive material parts 80 are placed so that they overlap the diagonal line DL2. In addition, more preferably four adhesive material parts 80 other than the one adhesive material part 80 at the center are placed so that their respective centers are positioned at the corners of a rectangle.

If there are four adhesive material parts 80, preferably two adhesive material parts 80 are placed so that they overlap, of the two diagonal lines DL1, DL2 drawn across the bottom face region of the multilayer ceramic capacitor 50, the diagonal line DL1, while two adhesive material parts 80 are placed so that they overlap the diagonal line DL2, just like in the embodiment shown in FIG. 7A. In addition, more preferably the four adhesive material parts 80 are placed so that their respective centers are positioned at the corners of a rectangle.

If there are three adhesive material parts 80, preferably one adhesive material part 80 is placed so that it overlaps, of the two diagonal lines DL1, DL2 drawn across the bottom face region of the multilayer ceramic capacitor 50 and one width-direction center line CL1, the diagonal line DL1, while one adhesive material part 80 is placed so that it overlaps the diagonal line DL2, and one adhesive material part 80 is placed so that it overlaps the width-direction center line CL1, just like in the embodiment shown in FIG. 7 (B). In addition, more preferably the three adhesive material parts 80 are placed so that their respective centers are positioned at the corners of an isosceles or regular triangle.

By adopting the aforementioned placement positions according to the number of adhesive material parts 80, the multilayer ceramic capacitor 50 can be supported in a stable manner with the adhesive material parts 80 and space-setting members 81, and high parallelism can be ensured for the multilayer ceramic capacitor 50 and interposer 60.

Next, preferred examples of how the multilayer ceramic capacitor with interposer CWI2 shown in FIGS. 8 and 9 is produced are explained using FIGS. 8 to 10.

For production, a multilayer ceramic capacitor 50 and an interposer 60, as shown in FIGS. 8 and 9, are prepared. Next, a paste for adhesive material part 80 is printed on the top face region of the interposer 60 excluding the connection electrodes 62, 63, by means of screen printing, gravure printing, or other printing method, to form the necessary number of uncured adhesive material parts 80 (refer to FIG. 10). Next, space-setting members 81 are embedded into the uncured adhesive material parts 80. This embedding step may be omitted by mixing the space-setting members 81 into the paste for adhesive material part 80 beforehand. Next, the multilayer ceramic capacitor 50 is installed on the interposer 60 by pressing its bottom face region, excluding the external electrodes 52, 53, onto the uncured adhesive material parts 80. Next, the uncured adhesive material parts 80 are cured by blowing hot air onto them, heating them in an oven, or using another method, to bond the multilayer ceramic capacitor 50 to the interposer 60. Next, the first external electrode 52 of the multilayer ceramic capacitor 50 is joined to the first connection electrode 62 of the interposer 60 using solder or other joining material 70, while at the same time the second external electrode 53 is joined to the second connection electrode 63 of the interposer 60 using solder or other joining material 70.

Next, the effects achieved by the multilayer ceramic capacitor with interposer CWI2 shown in FIGS. 8 and 9 are explained.

(1) The multilayer ceramic capacitor with interposer CWI2 has adhesive material parts 80 provided between the multilayer ceramic capacitor 50 and interposer 60, and the adhesive material parts 80 include space-setting members 81 for setting the spacing between the multilayer ceramic capacitor 50 and interposer 60. This means that, because the spacing between the multilayer ceramic capacitor 50 and interposer 60 can be set by the space-setting members 81, the height-direction dimension H of the multilayer ceramic capacitor with interposer CWI2 itself does not vary excessively. This removes concerns that the multilayer ceramic capacitor 50 may crack, chip, or otherwise suffer damage, or may not be installed properly when the multilayer ceramic capacitor with interposer CWI2 is installed on a circuit board, etc., using a mounter.

(2) The multilayer ceramic capacitor with interposer CWI2 has, around the adhesive material parts 80 between the multilayer ceramic capacitor 50 and interposer 60, a space SP that opens to the outside. This means that, even when the temperature of the interposer 60 rises in a state where the multilayer ceramic capacitor with interposer CWI2 is mounted on a circuit board, etc., this heat can be released to the outside by utilizing the space SP, which in turn keeps the temperature of the multilayer ceramic capacitor 50 from rising due to heat conduction from the interposer 60 and thereby prevents, to the maximum extent possible, any capacity drop or other functional problem that might otherwise occur in the multilayer ceramic capacitor 10 due to temperature rise.

(3) By providing three or more adhesive material parts 80 on the multilayer ceramic capacitor with interposer CWI2, the multilayer ceramic capacitor 50 can be supported in a stable manner by the adhesive material parts 80 and space-setting members 81.

### Other Embodiments

(1) The <<First Embodiment>> section and <<Second Embodiment>> section above each described an electronic component with interposer constituted by an interposer and one multilayer ceramic capacitor installed on it; however, effects similar to those described in each section can be achieved even when two or more multilayer ceramic capacitors are installed.

(2) The <<First Embodiment>> section and <<Second Embodiment>> section above each described an electronic component with interposer whose electronic component part is a multilayer ceramic capacitor; however, effects similar to those described in each section can be achieved even when an electronic component other than multilayer ceramic capacitor, such as a laminated ceramic inductor, for example, is installed on an interposer.

In the present disclosure where conditions and/or structures are not specified, a skilled artisan in the art can readily provide such conditions and/or structures, in view of the present disclosure, as a matter of routine experimentation. Also, in the present disclosure including the examples described above, any ranges applied in some embodiments may include or exclude the lower and/or upper endpoints, and any values of variables indicated may refer to precise values or approximate values and include equivalents, and may refer to average, median, representative, majority, etc. in some embodiments. Further, in this disclosure, “a” may refer to a species or a genus including multiple species, and “the invention” or “the present invention” may refer to at least one of the embodiments or aspects explicitly, necessarily, or inherently disclosed herein. The terms “constituted by” and “having” refer independently to “typically or broadly comprising”, “comprising”, “consisting essentially of”, or “consisting of” in some embodiments. In this disclosure, any defined meanings do not necessarily exclude ordinary and customary meanings in some embodiments.

The present application claims priority to Japanese Patent Application No. 2016-075629, filed Apr. 5, 2016, the disclosure of which is incorporated herein by reference in its entirety including any and all particular combinations of the features disclosed therein.

It will be understood by those of skill in the art that numerous and various modifications can be made without departing from the spirit of the present invention. Therefore, it should be clearly understood that the forms of the present invention are illustrative only and are not intended to limit the scope of the present invention.

We/I claim:

1. An electronic component with interposer, comprising an electronic component and an interposer attached thereto, wherein the electronic component adheres to the interposer using an adhesive material part provided therebetween, and the adhesive material part includes a space-setting member for setting a spacing between the electronic component and the interposer, wherein the spacer setter does not constitute an adhesive material included in the adhesive material part and has a thickness which sets the spacing.

2. An electronic component with interposer according to claim 1, wherein a space that opens to an outside exists around the adhesive material part between the electronic component and the interposer.

3. An electronic component with interposer according to claim 1, wherein the adhesive material part is provided at three or more locations which are positioned away from each other.

4. An electronic component with interposer according to claim 2, wherein the adhesive material part is provided at three or more locations which are positioned away from each other.

5. An electronic component with interposer according to claim 1, wherein a number of the space-setting member included in the adhesive material part is at least one.

6. An electronic component with interposer according to claim 2, wherein a number of the space-setting member included in the adhesive material part is at least one.

7. An electronic component with interposer according to claim 3, wherein a number of the space-setting member included in the adhesive material part is at least one.

8. An electronic component with interposer according to claim 4, wherein a number of the space-setting member included in the adhesive material part is at least one.

9. An electronic component with interposer according to claim 1, wherein the interposer has on one side a number of connection electrodes corresponding to a number of external electrodes of the electronic component, and also has on another side a number of mounting electrodes corresponding to a number of the connection electrodes, where the corresponding pairs of the connection electrodes and the mounting electrodes are connected by connection conductors, respectively.

10. An electronic component with interposer according to claim 1, wherein the space-setting member is made of ceramic, metal, inorganic substance, or synthetic resin.

11. An electronic component with interposer according to claim 1, wherein the spacer-setting member has a shape of a sphere, ellipsoid, cube, or rectangular solid.
